(19) United States
(12) Patent Application Publication
(10) Pub. No.: US 2008/0230802 A1
(43) Pub. Date: Sep. 25, 2008

(54) Semiconductor Device Comprising a Heterojunction

(76) Inventors: Erik Petrus Antonius Maria Bakkers, Eindhoven (NL); Robertus Adrianus Maria Wolters, Eindhoven (NL); Johan Hendrik Klootwijk, Eindhoven (NL)

Correspondence Address: PHILIPS INTELLECTUAL PROPERTY & STANDARDS, PO BOX 3001, BRIARCLIFF MANOR, NY, 10510-8001, US

(21) Appl. No.: 10/583,797

(22) PCT Filed: Dec. 13, 2004
(86) PCT No.: PCT/IB2004/052785

§ 371 Date: Jun. 21, 2006

(30) Foreign Application Priority Data
Dec. 23, 2003 (EP) 03104933.1

(51) Int. Cl. H01L 29/04; H01L 21/20

(52) U.S. Cl. 257/190; 438/481; 257/E21.131; 257/E29.003

(57) ABSTRACT

A semiconductor device with a heterojunction. The device comprises a substrate and at least one nanostructure. The substrate and nanostructure is of different materials. The substrate may e.g. be of a group IV semiconductor material, whereas the nanostructure may be of a group III-V semiconductor material. The nanostructure is supported by and in epitaxial relationship with the substrate. A nanostructure may be the functional component of an electronic device such as a gate-around-transistor device. In an embodiment of a gate-around-transistor, a nanowire (51) is supported by a substrate (50), the substrate being the drain, the nanowire the current channel and a top metal contact (59) the source. A thin gate dielectric (54) is separating the nanowire and the gate electrode (55A, 55B).

The invention relates to integration of different materials in a single electric device. The invention relates particularly to heterojunction between materials in an electric device and more particularly to the growth of one or more nanostructures of a first material on a substrate of a second material.

The semiconductor industry can be divided into three main sub-industries based upon the three most applied semiconductor technologies: silicon (Si), gallium arsenide (GaAs) and indium phosphide (InP). The silicon technology is the most dominant technology in terms of application and maturity, however the physics of silicon limits its application in high-frequency applications and optical applications, where gallium arsenide and indium phosphide are the most appropriate materials. The large lattice mismatch and thermal mismatch between silicon being a group IV semiconductor material, and gallium arsenide and indium phosphide both being group III-V materials render the integration on a single chip difficult for the three materials.

Integration of group III-V semiconductors on silicon substrates has received significant interest due to the potential of combining complementary III-V device technologies and performances, such as opto-electronics and high-frequency devices, with the silicon technology, e.g. the CMOS technology.

Group III-V semiconductor materials may be accommodated on, or integrated with, group IV semiconductor materials by using one or more buffer layers.

In the US patent application 2003/0038299 mono-crystalline GaAs layers may be grown on a silicon substrate by using two subsequent buffer layers, e.g. silicon oxide and strontium titanate. These buffer layers are used to accommodate some of the lattice mismatch between the layers.

Disadvantages of applying buffer layers, as done in the above-mentioned prior art, may include that no electrical contact is present between the upper layer and the substrate, the number of distinct process steps in order to form the buffer layers, that it is expensive to growth the buffer layers, etc.

The present invention seeks to provide an improved electric device. Preferably, the invention alleviates or mitigates one or more of the above or other disadvantages singly or in any combination.

Accordingly there is provided, in a first aspect, an electric device comprising:

a substrate having a main surface of a first material, and

a nanostructure of a second material,

wherein the first and second materials having a mutual lattice mismatch, and wherein the nanostructure being supported by and being in epitaxial relationship with the substrate.

The first material may comprise at least one element from a first group in the periodic table and the second material may comprise at least one element from a second group, the second group being different from the first group.

The electric device may be an electronic device, a light-emitting device, such as a light emitting diode or display device, or any other type of electric device.

The first and second materials may be selected from the group consisting of group IV materials, group III-V materials and group II-VI materials. The first and second materials may be insulating materials, i.e. materials with such low conductivity that the flow of current through them may be neglected, they may be conducting materials, i.e. materials with a conductivity of that of metals, or they may be semiconductor materials, i.e. materials with a conductivity intermediate between an insulator or a metal, and where the conductivity may depend on various properties such as the impurity level. The first and second materials need not be of the same conductivity, i.e. one may be an insulator while the other may be a semiconductor, but both materials may also be of the same conductivity, such as both materials may be semiconductor materials.

The first and second materials may each include more than one element from the periodic table, i.e. the first and/or second materials may each be a binary, a ternary, or a quaternary compounds, or may each be a compound containing more than five elements. The first material may e.g. be a group IV semiconductor material, such as silicon or silicon-germanium (SiGe), and the second material may be a group III-V semiconductor material, such as InP or GaAs. The substrate need not be a substrate of a bulk material. The substrate may be a top layer of the first material supported by a bulk material of the same or a different material. The substrate may even be a stack of layers supported by a bulk material, where the top layer of the stack of layers is of the first material. As an example, the substrate may be a top layer of SiGe supported by a Si substrate, e.g. as Si wafer.

By providing a nanostructure of a second material, instead of an overlayer of the second material, problems with e.g. lattice mismatch between the two materials may be reduced. A possible lattice mismatch between a second material supported on a first material, need not cause strain to build up in the nanostructure. Strain may be relieved on the surface of the nanostructure, thereby rendering a nanostructure with very few defects, or even defect-free, possible, and further rendering possible an epitaxial relationship between the nanostructure and the substrate.

The invention is based on the insight that it is not possible to grow epitaxial overlayers above a certain thickness of certain materials on top of certain substrates. For example, it is not possible to grow an epitaxial overlayer with a thickness larger than approximately 20 nm of InP on a substrate of group IV such as SiGe due to the strain resulting from the lattice mismatch. By providing nanostructures in epitaxial relationship with a substrate, it may be possible to grow structures with larger thickness than what may be obtained with an overlayer of the same material. Nanowires of InP structures with longitudinal dimensions larger than 20 nm may be brought into epitaxial relationship with a SiGe substrate because due to the limited lateral dimension the strain is relatively small and may be relaxed at the surface of the nanostructure.

The nanostructure may be an elongated structure projecting away from the substrate. The elongated nanostructure may possess a specific aspect ratio, i.e. with a specific length-to-diameter ratio. The aspect ration may be larger than 10, such as larger than 25, such as larger than 50, such as larger than 100, such as larger than 250. The diameter may be obtained perpendicularly to the longitudinal direction of the nanostructure.

The nanostructure may be in electrical contact with the substrate. It may be a prerequisite that an electrical contact is present between the first and second materials in order to obtain complete integration of the first and second materials in an electric device.

The electrical contact may be a so-called Ohmic contact, an expression which is used in the art for a low resistance contact. The resistance between the nanostructure and the substrate may at room temperature be below 10⁻⁵ Ohm cm², such as below 10⁻⁶ Ohm cm², such as below 10⁻⁷ Ohm cm², such as below 10⁻⁸ Ohm cm², such as below 10⁻⁹ Ohm cm², or even lower. It is an advantage to obtain as low a resistance as possible in order to reduce e.g. heat dissipation in the contact area.

The lattice mismatch between the substrate and the nanostructure may be smaller than 10%, such as smaller than 8%, such as smaller than 6%, such as smaller than 4%, such as smaller than 2%. The lattice mismatch may be larger than 0.1%, larger than 1% and/or larger than 2%. As an example of lattice mismatches between group III-V and group IV semiconductor materials, the lattice mismatch between InP and Ge and Si is 3.7% and 8.1%, respectively. It is an advantage that it may be possible to provide epitaxial relationship between two materials having such relative large lattice mismatches. It is expected that the larger the lattice mismatch, the thinner the nanostructures which may be obtained in epitaxial relationship with the substrate.

The nanostructure may be in the form of a nanotube or a nanowire, or a mix where both tubes and wires are present. A nanotube may be an elongated nanostructure with a hollow core, whereas a nanowire may be an elongated nanostructure with a massive core of the same material as the mantle. The core and the mantle of the nanowire may have different structure, if e.g. strain due to a lattice mismatch is relieved on the surface of the nanowire. The nanowire may also be an elongated nanostructure with a massive core of a different material than that of the mantle.

The nanostructure may be a substantially single-crystal nanostructure. It may be advantageous to provide single-crystal nanostructure, e.g. in relation with theoretical elaboration of current transport through the nanostructure, or other types of theoretical support or insight into properties of the nanostructure. Further, other advantages of substantially single-crystal nanostructure include that a device with a more well-defined operation may be achieved, e.g. a transistor device with a better defined voltage threshold, with less leak current, with better conductivity, etc. may be obtained, than for devices based on non-single crystal nanostructures.

The nanostructure may be intrinsic semiconducting, doped to be p-type semiconducting or doped to be n-type semiconducting. Further, the nanostructure may comprise at least two segments, and where each segment is either an intrinsic semiconductor, or an n-type semiconductor or a p-type semiconductor. Different types of semiconductor device components may therefore be provided, such as components comprising a pn-junction, a pnp-junction, a npn-junction, etc. Segments in the longitudinal direction may e.g. be obtained using a vapour deposition method, and during growth change the composition of the vapour.

The nanostructure may be the functional component of a device selected from the group consisting of phonon bandgap devices, quantum dot devices, thermoelectric devices, photonic devices, nanoelectromechanical actuators, nanoelectromechanical sensors, field-effect transistors, infrared detectors, resonant tunneling diodes, single electron transistors, infrared detectors, magnetic sensors, light emitting devices, optical modulators, optical detectors, optical waveguides, optical couplers, optical switches, and lasers.

A plurality of nanostructures may be arranged in an array. By arranging the nanostructures in an array, integrated circuit devices comprising a multitude of single electronic components, such as a multitude of transistor components, may be provided. The array of the nanostructures may be provided in combination with selection lines or a selection grid for addressing individual nanostructures, or a group of nanostructures.

The electric device may be a transistor, such as a transistor of the gate-around type. The electric device may thus comprise a source, a drain, a current channel, a gate-dielectric and a gate. The drain may e.g. be provided by at least a section of the substrate.

A first dielectric may be present in the electronic device. The first dielectric may be in contact with at least a section of the nanostructure. The nanostructure may in certain embodiments act as a current carrying channel, e.g. the current channel in a transistor device. The first dielectric may be, or may provide, a dielectric barrier separating the substrate from one or more gate electrodes. The first dielectric may be of any suitable material, such as SiO₂ or Spin-on-glass (SOG). The first dielectric may be provided as a layer of a certain thickness, such as in the range 10-1000 nm, such as in the range 50-500 nm, such as in the range 100-250 nm. The first dielectric may be provided with a dielectric coupling so as to obtain a low, a negligible or no parasitic capacitance between the substrate and the gate electrode. The first dielectric may be provided with a dielectric constant lower than the dielectric constant of SiO₂, the first dielectric layer may be a low-K material, such materials are known in the art. Examples of low-K materials which may be used are such materials as: SiLK (trademark of Dow Chemical), Black diamond (trademark of Applied Materials) and Aurora (trademark of ASMI).

The device may further comprise a first conductive material and wherein the first conductive material is in contact with at least a section of the first dielectric. The first conductive material may be an electrode, such as a gate electrode.

The device may further comprise a second conductive material and wherein the second conductive material is in contact with at least one nanostructure. The second conductive material may act as a top contact. The top contact may act as the source or drain of a transistor.

The first and second conductive materials may be of any suitable materials, e.g. a metal, a conductive polymer or another type of conducting materials, such as indium tin oxide (ITO). The first and second conductive materials may be of the same or different materials. The first and second conductive materials may be provided with a certain thickness, such as in the range 10-1000 nm, such as in the range 50-500 nm, such as in the range 100-250 nm. The first and second conductive materials may be electrically connected by the nanostructure, and depending upon the conductivity of the nanostructure, a conducting or a semiconducting connection may be obtained.

The device may further comprise a second dielectric and wherein the second dielectric is separating the first conductive material from the nanostructure.

The second dielectric may provide an insulating barrier between the first conductive material and the nanostructure, in certain embodiments of the present invention, the second dielectric may provide a gate dielectric. The second dielectric may be of any suitable material, such as SiO₂. The second dielectric may be provided with a certain thickness, such as in the range 1-100 nm, such as in the range 10-75 nm, such as in the range 20-50 nm. The thickness of the second dielectric material may be chosen so as to obtain a sufficient electrical insulation between the first conductive material and the nanostructure. Especially the lower limit of the thickness of the second dielectric material may depend upon that a sufficient electrical insulation is obtained. The second dielectric may be provided with a dielectric constant higher than the dielectric constant of SiO₂, the at second dielectric may be a high-K material, such materials are known in the art. Examples of High-K materials which may be used are such materials as tantalum oxide or hafnium oxide.

The device may further comprise at least a third dielectric. The at least third dielectric may be a stack of layers. The at least third dielectric may separate the second conductive material and the first conductive material. The at least third dielectric may be of any suitable material, such as SiO₂, SOG or a spin-on-polymer such as a photoresist layer. An advantage of a photoresist layer is that it may act as a self-assembled vertical mask. The at least third dielectric may be provided with a certain thickness, such as in the range 10 nm to 5 micron, such as in the range 100 nm to 2 micron, such as in the range 250 nm to 1 micron, such as 500 nm. The at least third dielectric may, similarly to the first dielectric layer be of a low-K material.

The first and at least third dielectric layer may each have a thickness which is larger than the thickness of the second dielectric layer. The difference may be a factor of 10 or more. The thickness ratio between the first dielectric layer and the second dielectric layer, and/or the thickness ratio between the at least third dielectric layer and the second dielectric layer may be obtained with respect to geometrical thickness, however the thickness ratio may also be obtained normalized with the dielectric coupling constants of the respective layers.

According to a second aspect of the invention, there is provided a method of growing a second material in epitaxial relationship with a first material, the second material and the first material having a mutual lattice mismatch, the method comprising the steps of:

providing a substrate of the first material,

forming a nanostructure of the second material by a growth method,

wherein the first material comprising at least one element from a first group in the periodic table and the second material comprising at least one element from a second group, the second group being different from the first group, and wherein the nanostructure being supported by and in epitaxial relationship with the substrate.

The nanostructure may be grown according to the vapour-liquid-solid (VLS) growth mechanism. In VLS growth, a metal particle is provided onto the substrate at positions where the nanostructure is to be grown. The metal particles may be a metal or an alloy comprising a metal selected from the group consisting of: Fe, Ru, Co, Rh, Ni, Pd, Pt, Cu, Ag, Au.

The nanostructure may however also be grown using different growth methods. For example, the nanostructure may be grown epitaxially in a contact hole from a vapour phase or liquid phase, i.e. a hole in a dielectric layer covering the substrate except for the position of the nanostructure.

Reference made to a nanostructure, the nanostructure, one nanostructure etc. does not indicate that reference is made only to a single nanostructure. More than one nanostructure, such as a plurality of nanostructures is also covered by such references.

These and other aspects, features and/or advantages of the invention will be apparent from and elucidated with reference to the embodiments described hereinafter.

Embodiments of the invention will be described, by way of example only, with reference to the drawings, in which:

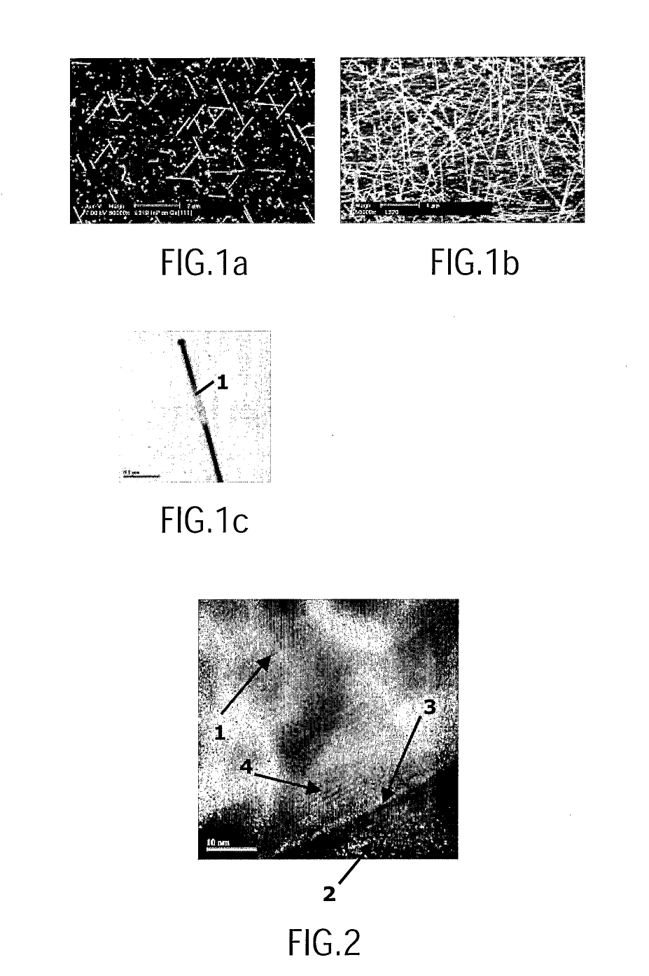

FIG. 1 shows SEM images of InP nanostructures grown on Ge(111),

FIG. 2 shows a HRTEM image of the interface between an InP nanostructure in contact with Ge(111),

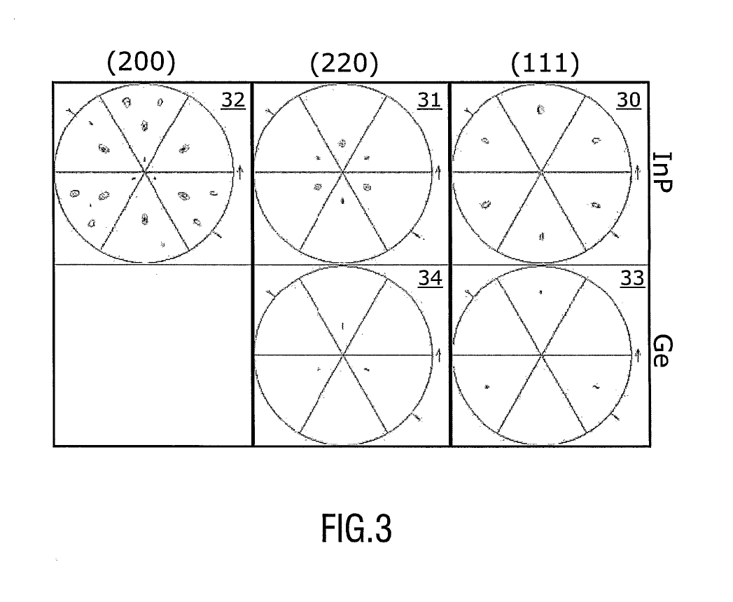

FIG. 3 shows XRD pole diagrams of InP nanostructures grown on Ge(111),

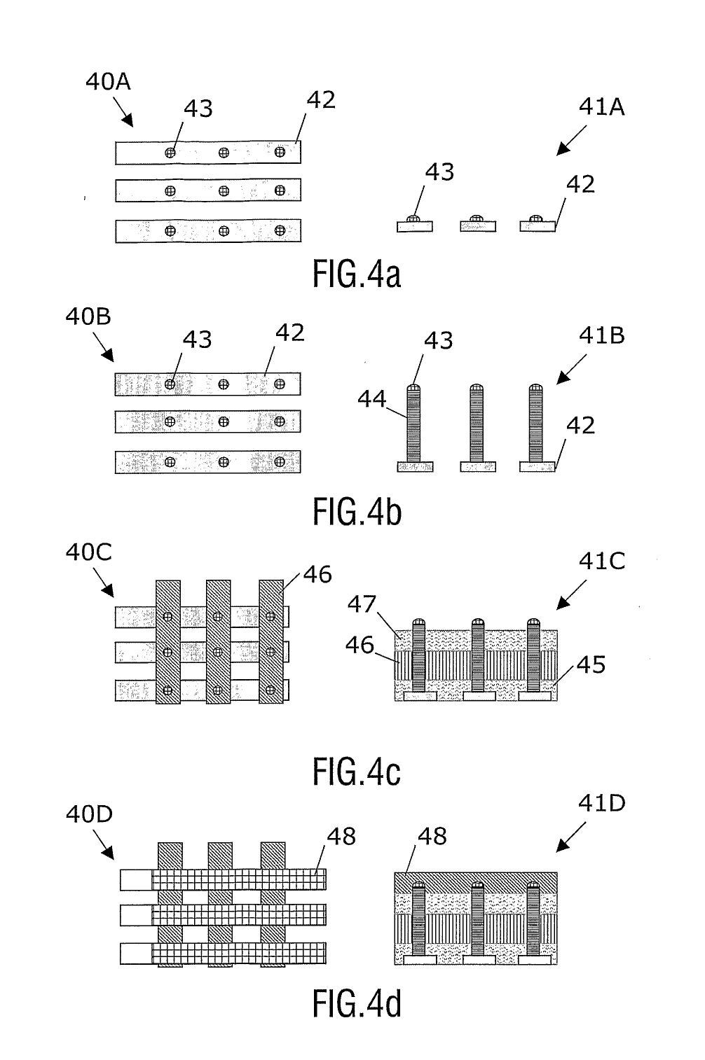

FIG. 4 is a schematic illustration of process steps involved in providing an array of gate-around-transistors,

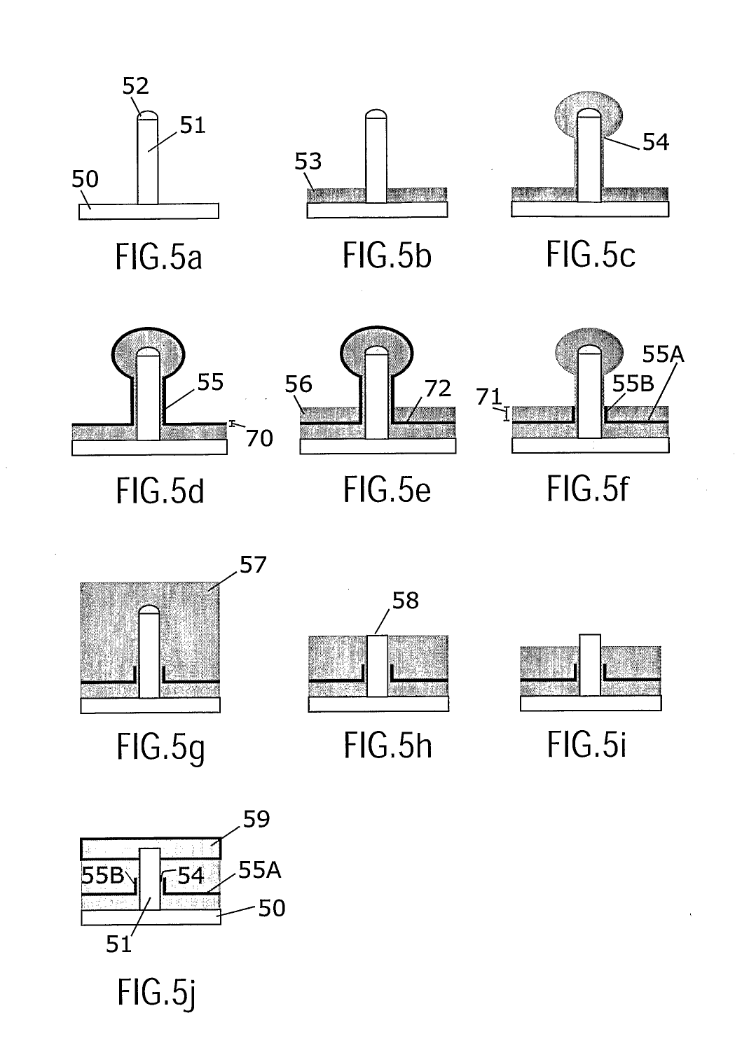

FIG. 5 is a schematic illustration of process steps involved in providing a first embodiment of a gate-around-transistor, and

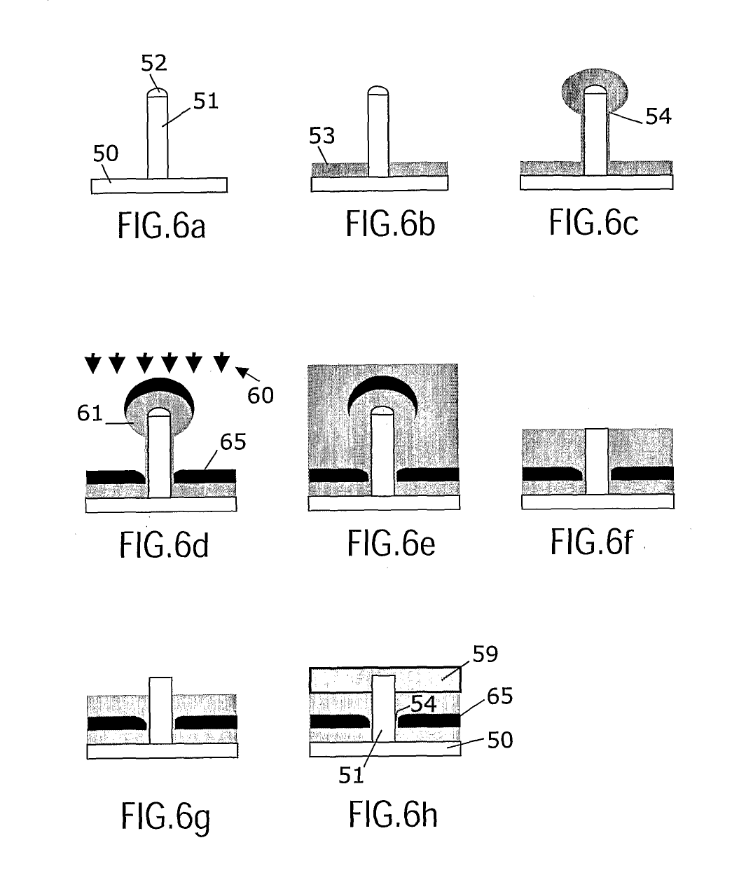

FIG. 6 is a schematic illustration of process steps involved in providing a second embodiment of a gate-around-transistor.

Throughout this section reference is made to nanowires rather than to the broader term nanostructures used elsewhere in the text. The term nanowire is used in connection with the description of specific embodiments described in this section and should be taken as an example of a nanostructure, not as a limitation of the term nanostructure.

In FIGS. 1 to 3, various aspects of InP nanowires (group III-V) grown on Ge(111) (group IV) are illustrated.

The nanowires were growth using the VLS-growth method. The equivalent of a 2 Angstrom (Å) gold layer was deposited on a cleaned Ge(111) substrate. The substrate was before the deposition of gold cleaned by dipping it in buffered HF solution. The substrate was maintained at a temperature in the range 450 to 495° C. while an In and P concentration was established using laser ablation, and maintained during the growth of the nanowires.

FIG. 1(a) is a top view scanning electron microscopy (SEM) image. The nanowires are imaged bright, and it is clear that the nanowires have a crystallographic three-fold symmetry orientation. In FIG. 1(b) a side view is provided, and it may be seen that most of the nanowires are grown vertically on the substrate, even though some of the nanowires are at an angle of 35° with respect to the substrate. In FIG. 1(c) a single wire 1 is imaged.

In FIG. 2 a high-resolution transmission electron microscopy (HRTEM) image of an InP wire 1 on a Ge(111) substrate 2 is illustrated. An atomically sharp interface 3 between the wire and the substrate is readily recognized. Some stacking faults 4 (3 to 5 twinning planes) are present, however the stacking faults are grown out after 20 nm. Further, it may be observed that the Ge lattice (direction) continues in the InP lattice, meaning the wires really grow epitaxially.

The epitaxial relationship between the nanowire and the substrate is further elaborated upon in connection with FIG. 3. In FIG. 3 X-ray diffraction (XRD) pole diagrams of InP nanostructures grown on Ge(111) are shown.

In the figure five sets of spots are shown, the (111), (220) and (200) spots are shown for InP 30, 31, 32, whereas only the (111) and (220) spots are shown for Ge 33, 34. The reflections of the InP crystal appear at identical orientations with respect to the Ge reflections. Thus, the wires indeed grow epitaxially. Besides the identical orientation also a 180 degrees in-plane rotation can be observed. This is either due to the fact that InP crystals consist of two atoms and Ge of one, and the wires can grow in two orientations on the Ge, or that a rotational twin in the [111] direction is present.

InP nanowires grown on Ge(111) are provided as an example, different types of nanowires may be grown on the same or different substrates within the scope of the present invention. As a specific example, nanowires may also be grown on the technological important surface of Si(100) or Ge(100). In this case the nanowires then grow along the [100] direction.

In FIG. 4 four process steps ((a) to (d)) involved in providing an array of gate-around-transistors are schematically illustrated. The figures on the left side (40A, 40B, 40C and 40D) provide a top-view, whereas the figures on the right side (41A, 41B, 41C and 41D) illustrate the corresponding side-view of the process steps.

In the first process step (FIG. 4(a)) rows 42 of the substrate material are firstly provided. The rows may be provided using a lithography process. The substrate may be of a group II-VI material, a group III-V material, or a group IV material, such as Ge or Si or a mixture thereof. Subsequently, metal particles 43, such as gold particles, are provided in arrays along the substrate rows. The rows may be doped to increase the conductivity.

In the process step illustrated in FIG. 4(b) nanowires of e.g. InP or another semiconductor material are grown using the VLS growth method. Nanowires 44 protruding from the substrate at the position of the metal particles are thereby provided.

In the process step in FIG. 4(c) a first dielectric material 45 is provided. Even though not explicitly illustrated a thin second dielectric layer is also provided along the nanowires (this will elaborated upon below). On top of the first dielectric layer is a first conducting material provided in rows 46. The rows may be provided using a suitable lithographic method. A third dielectric layer 47 is also provided on top of the first conducting material.

In the process step in FIG. 4(d) rows 48 of a second conductive material are provided. The second conductive material may act as a top contact.

Thus, by following the process steps illustrated in FIG. 4 electrical connection may be made to individual nanowires by controlling which set of rows 42, 46, 48 that is addressed. In this embodiment, only a single nanowire is present in the area covering the intersections of the rows. However, more than one nanowires, such as a bundle of nanowires may also be present in the areas covering the individual intersections.

In FIGS. 5 and 6 two embodiments of the process steps involved in the fabrication of a gate-around-transistor are shown. Firstly the embodiment illustrated in FIG. 5 is described, and subsequently the embodiment illustrated in FIG. 6. The embodiments focus on the fabrication of a single gate-around-transistor, however by combining the process steps with those described in connection with FIG. 4, an array of gate-around-transistors may be provided. Other schemes for providing an array of nanostructures may, however, also be envisioned.

In FIG. 5(a) a nanowire 51 is grown substantially vertically on a semiconductor substrate 50. The nanowire may be grown using the VLS growth method, resulting in that the nanowire is terminated at its free end by a metal particle 52.

In the subsequent process step as illustrated in FIG. 5(b), a first dielectric layer 53 is provided onto the substrate. The layer covers all parts of the substrate not in contact with a nanowire. The layer adjoins at least a section of the nanowire. The first dielectric layer may e.g. be a Spin-on-glass (SOG). The thickness of the layer is in the order of 100 nm. As will become evident below, the SOG is applied to electrically insulate the substrate 50 from the gate electrode 55A. The SOG is after deposition thermally annealed at 300° C. The SOG may e.g. be of the type provided by Tokyo ohka or Allied Signal.

In the subsequent step illustrated in FIG. 5(c) a second dielectric layer 54 is provided. The layer may have a thickness 70 in the order of 1-10 mm. The layer may e.g. be a SiO₂ layer deposited by plasma enhanced chemical vapour deposition (PECVD) or by atomic layer deposition (ALD). The layer is deposited while the sample temperature is maintained at T=300° C. In this way the complete sample is covered by a thin layer, however at edges more material will be deposited due to material transport properties. This effect is known in the art as shadowing effect (see e.g. Silicon Processing in the VLSI era, S. Wolf and R. N. Tauber, 6th ed., 1986, p. 186, Attice Press, Sunset Beach, Calif.). This dielectric layer is in direct contact with the first dielectric layer.

In the subsequent step illustrated in FIG. 5(d) a first conducting layer 55 is provided in the form of a thin (50 nm) metal layer. The first conducting layer is in this embodiment aluminum, but may e.g. be Pt, Zr, Hf, TiW, Cr, Ta or Zn, ITO or any other suitable material. The layer may be deposited by using a sputtering technique, or any other relevant technique.

In the next process step (FIG. 5(e)) a third dielectric layer 56 is provided. The third dielectric layer may be a of a similar thickness as the first dielectric layer. Third dielectric layer may be a second SOG layer or may be a layer of PMMA, PIQ or BCB spincasted on the metal layer.

The dielectric-metal interface 72 can be modified by a primer, for instance HMDS, to adjust the contact angle between the surface and the next layer. Alternatively, a thin (such as 50 nm) SiO₂ layer can be deposited directly on the metal by PECVD.

The part of the first conducting layer which is protruding above the third dielectric layer 56, is etched in a subsequent step as illustrated in FIG. 5(f). The thickness 71 of the third dielectric layer is larger than the thickness 70 of the first conductive layer. The difference in thickness may be a factor 10 or more. This thickness difference result in, after the etch process of the part of the first conducting layer which is protruding above the third dielectric layer, that the first conductive layer obtains an L-shape 55A, 55B. The etching may for an Al layer be performed using PES, whereas TiW may be etched using an H₂O₂/NH₄OH mixture, Pt may be etched using an HCl/HNO₃ mixture, Zn may by etched using HCl, Co and Ni may be etched using an H₂O₂/H₂SO₄ mixture and Ta, Zr and Hf may be etched using HF.

The third dielectric layer may be spincasted on the surface of the conducting layer before the etch process. The third dielectric layer may act as a vertical mask during the metal etch process. It is expected that the third dielectric layer will only cover the horizontal part of the metal film. The third dielectric layer may be a resist layer which is not structured by lithography, but by the surface structure itself, it may thus be a self-assembling resist layer. After etching the resist layer may be removed by dissolving it in boiling acetone.

The complete sample is subsequently, as illustrated in FIG. 5(g), covered by a forth dielectric layer 57 (˜2 microns thick). The layer may e.g. be a SiO₂ layer deposited by PECVD at T=300° C.

The sample is then polished until the top surface 58 of the nanowire is reached, or until a desired thickness is obtained (FIG. 5(h)) and the top of the fourth dielectric layer is removed such that a part of a nanowire is freed from the forth dielectric layer (FIG. 5(i)). The removal of the top of the polished layer may e.g. be obtained by etching. A SiO₂ layer may be etched in a buffered oxide etch such as NH₄F or HF.

In FIG. 5(j) a second conductive layer 59 is provided as a top layer, i.e. a top contact metal is deposited on the nanowire. A photoresist layer may be spincasted on top of the second conductive layer. The photoresist layer may be patterned in accordance with a desired pattern of the second conductive layer, e.g. a grid and metal pads may be provided. As examples of top contact metal pads, an Al/Au layer may be deposited for n-type InP nanowires, and an Zn/Au layer for p-type InP nanowires. Also a transparent electrode my be provided, such as an ITO electrode for opto-electronic applications, e.g. a LED on a Si-chip.

Thus, the electronic device as illustrated in FIG. 5(j) is a gate-around-transistor. The gate-around-transistor comprises a drain 50, a current channel 51, a source 59, a gate electrode 55, the gate electrode comprising an feed part 55A, and a part 55B encircling the nanotube, and a gate dielectric 54 separating the nanotube from the electrode.

In FIG. 6(a) to (h) an alternative embodiment and an alternative process diagram is presented. FIGS. 6(a) to (c) are similar to the process steps described in connection with FIGS. 5(a)-(c).

In the process step described in FIG. 6(d) the electrode 65 is deposited by means of thermal vapour deposition 60. A thin aluminum layer (50 nm) may e.g. be deposited. In the vapour deposition process, the bell-shaped 61 SiO₂-deposit at the top of the nanowire acts as a shadow mask.

The subsequent steps (e) to (h) are similar to the step described in connection with FIG. 5(g) to FIG. 5(j).

Thus, the main structural difference between the gate-around-transistor resulting from process described in connection with FIG. 5, and the gate-around-transistor resulting from the process described in connection with FIG. 6, is the geometrical aspects of the gate electrode.

The electronic device as illustrated in FIG. 6(h) is also a gate-around-transistor. The gate-around-transistor comprises a drain 50, a current channel 51, a source 59, a gate electrode 65, and a gate dielectric 54 separating the nanotube from the electrode.

The process steps described in connection with FIGS. 4-6 are described with the tacit structural feature that material of the nanowire comprising at least one component which is different from at least one component of the material of the substrate. Further, in these embodiments the nanowires are grown using the VLS growth methods. It is, however, important to notice that these process steps may provide a gate-around-transistor irrespectively of how the nanowires are provided. The sole requirement for the process steps to provide a gate-around-transistor, is to provide, as a starting point, a substantially vertical substantially cylindrical element protruding from substrate. The wires may as an example also be grown homoepitaxially such as Si wires on Si.

The process steps disclosed above in connection with FIGS. 5 and 6 provide a solution to the problem of shrinking the conventional MOSFET beyond the 50 nm technology node. The barrier at 50 nm is a fundamental physics barrier. Two of the often-cited problems are tunneling of charge carriers through the thin gate dielectric and control of the charge density in the active channel. An improvement of the current planar MOSFET structures is the implementation of a gate-around FET. In the gate-around geometry the gate capacitance has increased, giving a better electrostatic control of the channel.

Combined with the present invention a solution is thus offered to the combined problem of miniaturizing of semiconductor devices and the integration of different semiconductor materials, such as group III-V and group IV material, in a single semiconductor device.

However, in general fabricating a gate-around structure based on a vertical nanowire offers a number of advantages. An enhanced gate capacitance with respect to the gate-around geometry may be obtained. Furthermore, the nanowire element may be chosen based on the requirement of a given component. For example, if a better control of the charge density in the channel is desirable, a high-mobility material, such as InGaAs, may be grown as the channel.

Although the present invention has been described in connection with preferred embodiments, it is not intended to be limited to the specific form set forth herein. Rather, the scope of the present invention is limited only by the accompanying claims.

A semiconductor device with a heterojunction. The device comprises a substrate and at least one nanostructure. The substrate and nanostructure is of different materials. The substrate may e.g. be of a group IV semiconductor material, whereas the nanostructure may be of a group III-V semiconductor material. The nanostructure is supported by and in epitaxial relationship with the substrate. A nanostructure may be the functional component of an electronic device such as a gate-around-transistor device. In an embodiment of a gate-around-transistor, a nanowire 51 is supported by a substrate 50, the substrate being the drain, the nanowire the current channel and a top metal contact 59 the source. A thin gate dielectric 54 is separating the nanowire and the gate electrode 55A, 55B.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of other elements or steps than those listed in a claim. The word “a” or “an” preceding an element does not exclude the presence of a plurality of such elements.

1. An electric device comprising:
a substrate having a main surface of a first material, and
a nanostructure of a second material,
wherein the first and second materials having a mutual lattice mismatch, and wherein the nanostructure being supported by and being in epitaxial relationship with the substrate.

2. A device according to claim 1, wherein the nanostructure is in electrical contact with the substrate.

3. A device according to claim 2, wherein the resistance between the nanostructure and the substrate is below 10⁻⁵ Ohm cm².

4. A device according to claim 1, wherein the nanostructure is a nanotube and/or the nanostructure is a nanowire.

5. A device according to claim 1, wherein a lattice mismatch between the substrate and the nanostructure(s) is smaller than 10%.

6. A device according to claim 1, wherein the nanostructure is a substantially single-crystal nanostructure.

7. A device according to claim 1, wherein a plurality of nanostructures are arranged in an array.

8. A device according to claim 1, wherein the electric device is a gate-around transistor.

9. A device according to claim 8, further comprising a first dielectric and wherein the first dielectric is in contact with at least a section of the nanostructure(s).

10. A device according to claim 9, further comprising a first conductive material and wherein the first conductive material is electrically insulated from the substrate by the first dielectric.

11. A device according to claim 10, further comprising a second dielectric and wherein the second dielectric is electrically insulating the first conductive material from the nanostructure.

12. A device according to claim 11 wherein the first dielectric is thicker than the second dielectric.

13. A device according to claim 1, further comprising a second conductive material and wherein the second conductive material is in contact with at least one nanostructure.

14. A device according to claim 13, further comprising at least a third dielectric the at least third dielectric insulating the second conductive material from the first conductive material.

15. A method of growing a second material in epitaxial relationship with a first material, the second material and the first material having a mutual lattice mismatch, the method comprising the steps of:
providing a substrate of the first material,
forming a nanostructure of the second material by a growth method,
wherein the first material comprising at least one element from a first group in the periodic table and the second material comprising at least one element from a second group, the second group being different from the first group, and wherein the nanostructure being supported by and in epitaxial relationship with the substrate.

16. A method according to claim 15, wherein the nanostructure is grown according to the vapour-liquid-solid growth method.
